(19) United States
(12) Patent Application Publication
(10) Pub. No.: US 2025/0350490 A1
(43) Pub. Date: Nov. 13, 2025

(54) Wake-up Receiver in Controller-Area-Network Transceivers

(71) Applicant: Texas Instruments Incorporated, Dallas, TX (US)

(72) Inventors: Atul Kumar Singh, Mau (IN); Deep Banerjee, Bangalore (IN); Lokesh Kumar Gupta, Bangalore (IN)

(21) Appl. No.: 18/679,746

(22) Filed: May 31, 2024

Related U.S. Application Data
(60) Provisional application No. 63/646,173, filed on May 13, 2024.

(51) Int. Cl. H04L 12/40; H03K 17/687

(52) U.S. Cl. CPC H04L 12/40039; H03K 17/6871; H04L 12/40032; H04L 2012/40215

(57) ABSTRACT

A controller area network (CAN) transceiver including a transmitter, a receiver, a wake-up receiver including an attenuator, a gain stage, a comparator, a pulse filter, and wake-up monitor logic. The gain stage includes an offset generation circuit, a common-gate amplifier, and first and second resistors. The first and second resistors are coupled between outputs of the attenuator to develop a common mode voltage. The offset generation circuit is referenced to the common mode voltage. The pulse filter can include start/stop logic, a transistor, a third resistor and a first capacitor coupled to one input of a second comparator, and a fourth resistor and a second capacitor coupled to another input of the second comparator.

### CROSS-REFERENCE TO RELATED APPLICATIONS

This application claims the benefit of and priority to U.S. Provisional Application No. 63/646,173, filed May 13, 2024, which is hereby fully incorporated herein by reference.

### BACKGROUND

This specification relates to data communications, and more particularly to receiver circuitry for detecting wake-up pulses on a network bus.

Modern automobiles may incorporate as many as fifty or more computing devices, such as microprocessors and microcontrollers, for monitoring and controlling various functions. These functions include sophisticated engine control for attaining desired levels of performance, fuel economy, and environmental emission compliance, as well as advanced diagnostics, safety systems, comfort and convenience features, and the like. Electric and hybrid vehicles may also include processor and logic devices in the motor drive and charging subsystems. The distributed computing architecture implemented by these numerous computing devices has greatly reduced the amount of electrical wiring, and thus the weight, of the automobile.

The computing devices and subsystems within each vehicle communicate with one another to coordinate their operation. The Controller Area Network (CAN) standard (ISO 11898) and corresponding specifications (all of which are incorporated herein by reference), promulgated by the International Standardization Organization (ISO) and adopted in the industry, specify a format and protocol for the communication of digital information among modules in a vehicle. The CAN standard defines a multi-master serial broadcast communications protocol in which the traditional automobile complex wiring harness is replaced by a two-wire bus. Because many of the messages communicated within a vehicle (e.g., measurements of temperature, RPM, etc.) are relatively short, communications under the CAN standard take the form of short messages broadcast over the entire network, as opposed to point-to-point transmission of large blocks of data under the supervision of a central bus master.

The CAN standard implements balanced, differential signaling in the transmission of binary data signals over the network, at data rates of up to, for example, 8 Mbps according to CAN FD standard ISO 11898-2 (incorporated herein by this reference). This differential signaling prevents the external coupling of noise in that the signals vary symmetrically on the differential bus lines CANH and CANL, causing the combined noise contributions to destructively interfere. The high immunity to electrical interference provided by this signaling scheme, along with the ability to self-diagnose and repair data errors provided by the CAN standard, have led to the implementation of CAN networks in applications outside of the automotive sphere. For example, CAN networks are now also popular in a variety of industries including building automation, medical systems, and manufacturing operations.

Additional requirements apply to CAN networks implemented in safety critical applications, such as in the automotive context. For example, CAN transceivers should withstand and operate under high DC voltages (e.g., ±58V) on the CANH and CANL bus lines. One test of this ability is the Direct Power Injection (DPI) test, in which the transceiver device is stressed with injected high frequency power at certain device pins. The injected power is increased step-by-step until device failure.

CAN network nodes in automotive applications are commonly idle much of the time. To save power, CAN modules are placed in a standby or sleep mode in which little quiescent power is consumed during periods of inactivity. However, CAN transceivers should detect the presence of a differential signal on the CAN bus while in sleep mode, and wake up from the standby or sleep mode to respond to bus signals. CAN transceivers include a wake-up receiver circuit that detects a particular pattern of differential bus signals associated with a wake-up command during standby or sleep mode, and that issues a wake-up signal upon detection of that pattern. Low power consumption is desirable in wake-up receiver circuits, considering that the wake-up receiver is operable during the standby and sleep modes.

U.S. Pat. No. 10,771,280, commonly assigned herewith and incorporated herein by reference, describes a low power wake-up circuit for CAN transceivers.

### SUMMARY

According to an example, receiver circuitry includes a first circuit including a first transistor having first and second terminals and a control terminal, the second terminal coupled to the control terminal; a first resistor having a first terminal coupled to the second terminal of the first transistor, and having a second terminal; and a first current source coupled to the second terminal of the first resistor. The receiver circuitry further includes a second circuit that includes a second transistor having first and second terminals, and having a control terminal coupled to the second terminal of the first resistor; and a third transistor having first and second terminals, and having a control terminal coupled to the first terminal of the first resistor. The receiver circuitry further includes a second resistor having a first terminal coupled to a first input and to the first terminal of the second transistor, and having a second terminal coupled to the first terminal of the first transistor; and a third resistor having a first terminal coupled to a second input and to the first terminal of the third transistor, and having a second terminal coupled to the first terminal of the first transistor and to the second terminal of the second resistor. The receiver circuitry further includes a comparator having a first input coupled to the second terminal of the second transistor, and having a second input coupled to the second terminal of the third transistor.

According to another example, receiver circuitry includes an attenuator (410); a gain stage; a comparator having first and second inputs coupled to first and second outputs of the gain stage, respectively; and a pulse filter. The pulse filter includes logic circuitry having a first input coupled to the output of the comparator; a first transistor having a control terminal coupled to an output of the logic circuitry; a second comparator; a first resistor and a first capacitor coupled to the first transistor and to a first input of the second comparator; and a second resistor and a second capacitor coupled to the first transistor and to the second input of the comparator. The receiver circuitry further includes wake-up monitor logic having an input coupled to the output of the second comparator.

According to another example, a controller area network (CAN) transceiver includes a transmitter and a receiver coupled to first and second bus terminals, and a wake-up receiver. The wake-up receiver includes an attenuator coupled to the first and second bus terminals; a gain stage; a comparator; a pulse filter; and wake-up logic circuitry. The gain stage includes a first transistor; a first resistor coupled to the first transistor; a first current source coupled to the first resistor; a second transistor having a control terminal coupled to the second terminal of the first resistor; a second resistor coupled to the second transistor to a power supply terminal; a third transistor having a control terminal coupled to the first terminal of the first resistor; and a third resistor coupled to the third transistor. The gain stage further includes a fourth resistor having a first terminal coupled to a first output of the attenuator and to the second transistor; and a fifth resistor having a first terminal coupled to a second output of the attenuator and to the third transistor, and having a second terminal coupled to the first transistor and to a second terminal of the fourth resistor.

Example technical advantages enabled by one or more of these examples include a reduction in pulse width distortion in the wake-up receiver with variations in bus common mode voltage, high bandwidth performance, and good performance under stress voltages such as those encountered in Direct Power Injection testing. A pulse filter described in these examples enables the detection of wake-up pulses of a duration within a narrow specification window, providing a wake-up receiver capable of fast bus arbitration and good noise immunity. Other example technical advantages enabled by this disclosure are apparent from the following specification together with its drawings.

### BRIEF DESCRIPTION OF THE DRAWINGS

FIG. 1 is an electrical diagram, in block form, of an example controller area network (CAN).

FIG. 2 is an electrical diagram, in block form, of an example CAN transceiver.

FIG. 3A is a timing diagram illustrating dominant and recessive states according to CAN differential signaling.

FIG. 3B is a timing diagram illustrating an example wake-up pattern under the CAN specification.

FIG. 4 is an electrical diagram, in block form, of an example wake-up receiver.

FIG. 5A is an electrical diagram, in schematic form, of an example gain stage in the wake-up receiver of FIG. 4.

FIG. 5B is an electrical diagram, in schematic form, of another example gain stage in the wake-up receiver of FIG. 4.

FIG. 6 is an electrical diagram, in schematic form, of an example pulse filter in the wake-up receiver of FIG. 4.

FIG. 7 is a timing diagram illustrating example operation of the pulse filter of FIG. 6.

The same reference numbers or other reference designators are used in the drawings to illustrate the same or similar (in function and/or structure) features.

### DETAILED DESCRIPTION

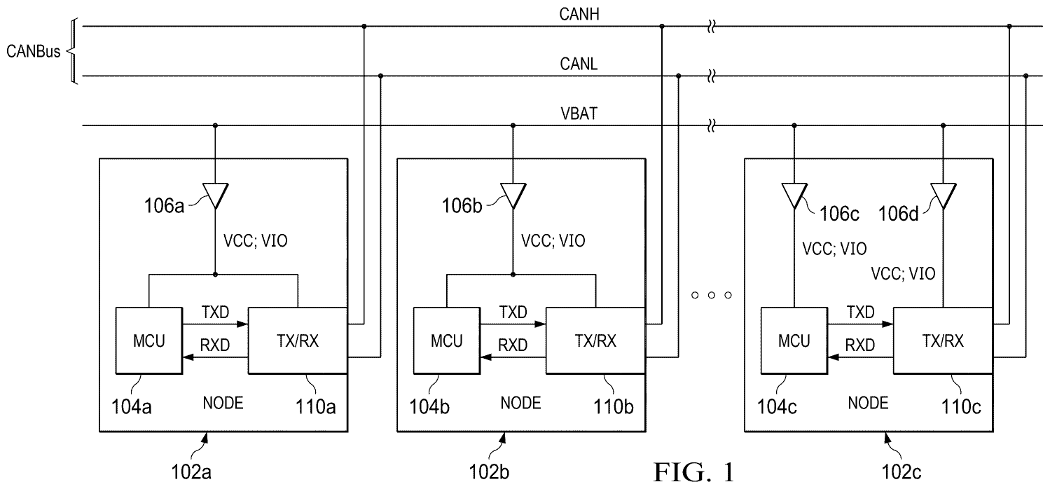

FIG. 1 illustrates a generalized architecture of a Controller Area Network (CAN) implemented according to the ISO 11898 standard promulgated by the International Standardization Organization (ISO) for intra-vehicle communication. The CAN of FIG. 1 includes bus CANBus, which includes wires CANH and CANL, and network nodes 102a, 102b, 102c. Network node 102a includes a microcontroller unit (MCU) 104a, a voltage regulator 106a, and a transceiver 110a. Network node 102b includes a microcontroller unit (MCU) 104b, a voltage regulator 106b, and a transceiver 110b. Network node 102c includes a microcontroller unit 104c, a pair of voltage regulators 106c and 106d, and a transceiver 110c.

As shown in FIG. 1, bus CANBus is a two wire bus including wires CANH and CANL, over which data signals are serially communicated among network nodes 102a, 102b, 102c (generically referred to as node or nodes 102). In an example, nodes 102 correspond to sensors, controllers, and/or other electronic subsystems within a vehicle, and are generally physically distributed throughout the vehicle. Each node 102 may include either or both analog and digital circuitry, which may include custom or programmable computational logic, arranged to carry out its intended function.

Each MCU 104a, 104b, 104c (generically referred to as MCU or MCUs 104) is coupled to a respective transceiver 110a, 110b, 110c (generically referred to as transceiver or transceivers 110) in its node 102. As shown in FIG. 1, each transceiver 110 is coupled to wires CANH, CANL of bus CANBus. Each transceiver 110 is constructed and operates to transmit and receive signals (e.g., data, command signals, control signals and/or instructions) to and from other nodes 102 in the network, via their respective transceivers 110. In this example, control signals on lines TXD, RXD are communicated between each transceiver 110 and its corresponding MCU 104. Within each node 102, line TXD carries data signals from MCU 104 to its transceiver 110, responsive to which the transceiver 110 transmits the corresponding differential signaling states onto bus CANBus. Line RXD communicates data signals received at bus CANBus by transceiver 110 to MCU 104.

Voltage regulators 106a, 106b, 106c, and 106d (generically referred to as voltage regulator or regulators 106) receive a power supply voltage from line VBAT, and generate voltages VCC, VIO, etc., for use within its corresponding network node 102. In this example, voltage regulators 106a and 106b supply a VCC power supply voltage (e.g., at a nominal voltage of 5V) to both MCU 104 and transceiver 110 in its corresponding network node 102. In network node 102c, voltage regulator 106c supplies a VCC power supply voltage at one nominal voltage (e.g., at 3V) to MCU 104c, and voltage regulator 106d supplies a VCC power supply voltage at another nominal voltage (e.g., at 5V) to transceiver 110c. Each of voltage regulators 106 may also generate other voltages, including in this example a digital I/O voltage VIO (e.g., nominally at 3.3V) for interface circuitry within MCUs 104 and transceivers 110.

In some implementations, other functions may also reside on bus CANBus. For example, a gateway (not shown in FIG. 1) may be provided on bus CANBus in some vehicles for communication with external systems, such as through an on-board diagnostic (OBD) port.

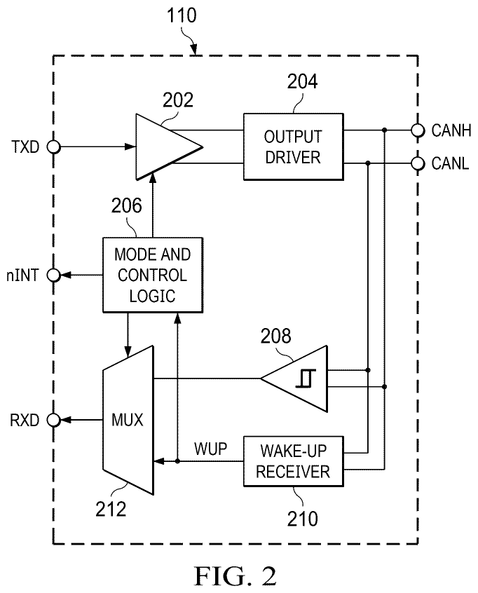

FIG. 2 illustrates an example CAN transceiver 110. CAN transceiver 110 may be a stand-alone transceiver integrated circuit device suitable for implementation in a CAN network node 102 of FIG. 1. Alternatively, CAN transceiver 110 may be embedded in a system-on-a-chip (SoC) integrated circuit together with an MCU, one or more voltage regulators, and other functions such as a system controller and the like. The architecture of CAN transceiver 110 shown in FIG. 2 is applicable to either implementation.

In the example of FIG. 2, CAN transceiver 110 includes transmit driver 202, output driver 204, mode and control logic 206, receiver 208, wake up receiver 210, and multiplexer 212. Other circuit functions not shown in FIG. 2, such as bus fault detection, over-temperature detection, undervoltage detection, clock and power circuitry, and the like may also be incorporated within CAN transceiver 110. CAN receiver 110 as shown in FIG. 2 has data bus line terminals CANH, CANL, data terminals TXD, RXD, and optional node interrupt terminal nINT.

On the transmit side of CAN transceiver 110, transmit driver 202 has an input coupled to data terminal TXD, from which it receives data from MCU 104 or another function in its network node 102. Transmit driver 202 receives control signals from mode and control logic 206, and has outputs coupled to inputs of output driver 204. Output driver 204 has outputs coupled to bus line terminals CANH, CANL. At such times as CAN transceiver 110 is to drive data signals onto CANBus, mode and control logic 206 enables transmit driver 202 to receive digital data at data terminal TXD. Transmit driver 202 drives output driver 204 according to the data levels at data terminal TXD. Output driver 204 in turn drives bus line terminals CANH, CANL to the appropriate differential signaling levels accordingly.

On the receive side of CAN transceiver 110, bus line terminals CANH, CANL are coupled to inputs of receiver 208. An output of receiver 208 is coupled to one input of multiplexer 212. Similarly, wake-up receiver 210 has inputs coupled to bus line terminals CANH, CANL, and an output coupled to another input of multiplexer 212 and also to an input of mode and control logic 206. In some examples, receiver 208 and wake-up receiver 210 may receive digital I/O voltage VIO as a power supply voltage. Alternatively, power supply voltage VCC may be supplied to receiver 208 and wake-up receiver 210. Mode control logic 206 applies control signals to multiplexer 212 for the selection of the output of receiver 208 or the output of wake-up receiver 210 to data terminal RXD for communication to MCU 104 or other circuitry in network node 102.

In this example, mode control logic 206 also has an output coupled to node interrupt terminal nINT. Mode and control logic 206 can operate to issue, in certain events, an interrupt signal at terminal nINT for communication to MCU 104 or other circuitry in network node 102. In the described examples, mode and control logic 206 can issue such an interrupt signal at terminal nINT following receipt of a valid wake-up pattern at bus CANBus as detected by wake-up receiver 210.

Other circuit functions may be included within CAN transceiver 110. Examples of such other functions include time-out circuitry, undervoltage and overtemperature detection circuits, bus fault detection circuits, and the like. Interface circuitry may additionally be coupled to data terminals TXD, RXD.

According to the ISO 11898 standard, the CAN network operates as a multi-master, message broadcast system, in that any of network nodes 102 can serve as the bus master for communications with one or more of the other nodes 102 using broadcast messaging. The CAN communication protocol is a carrier-sense, multiple-access protocol, in that each node 102 must wait for a specified interval of inactivity on bus CANBus before initiating transmission of a message. Under the ISO 11898 CAN standard, bus collisions among nodes 102 attempting to transmit simultaneously are resolved via bit-wise arbitration, based on the priority of each message as indicated in an identifier field of the message. The node 102 that is transmitting a message with the highest priority relative to the others always wins bus access.

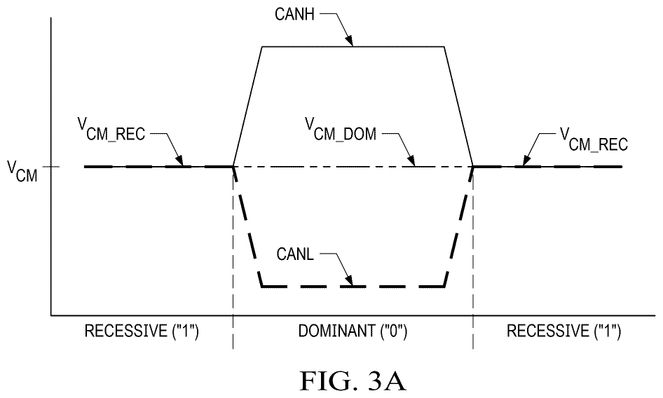

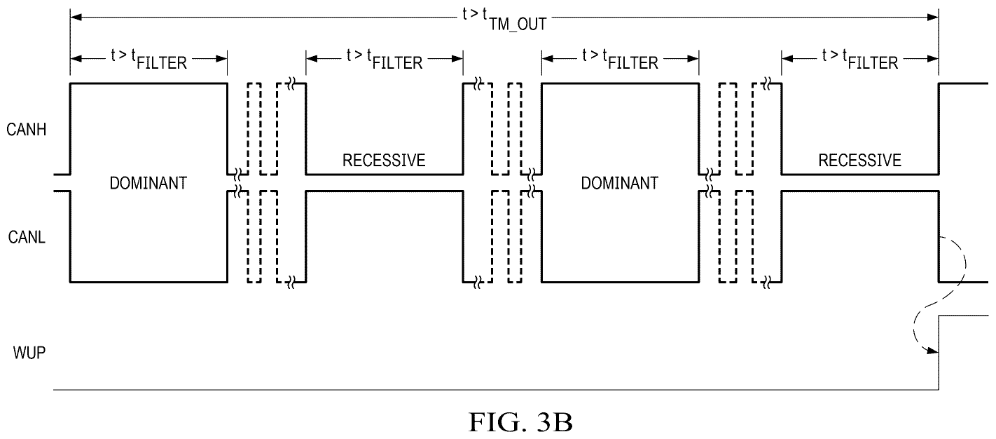

FIG. 3A illustrates the physical layer data signaling protocol according to the CAN standard as applied to bus CANBus of FIG. 1. As mentioned above, the ISO 11898 standard implements balanced, differential signaling. This signaling communicates the binary digital values “0” and “1” by way of the “dominant” and “recessive” differential states, respectively.

As shown in FIG. 3A, the dominant state is communicated on bus CANBus by an output driver 204 in one of network nodes 102 sourcing current onto bus line CANH and sinking current from bus line CANL. This drive current flows through termination resistors in one or more of nodes 102 to establish a differential voltage on the bus, with bus line CANH at a higher voltage than bus line CANL. The dominant state is indicated under the ISO 11898 standard by this differential voltage exceeding a specified minimum threshold level, and is interpreted as a logic low (“0”) level. A common mode bus voltage VCM_DOM is defined at the midpoint of these two levels. In operation, only one transceiver 110 in the network can drive the dominant state at any given time. During arbitration, however, multiple nodes 102 may transmit a dominant bit at the same time, in which case the differential voltage of the bus may be greater than the differential voltage from a single driver.

Conversely, the recessive state is communicated on bus CANBus by output driver 204 presenting a high impedance to lines CANH, CANL, while a common mode voltage buffer in the receiver 208 of each node 102 biases both of lines CANH, CANL to a common mode voltage VCM_REC. The differential voltage on bus lines CANH, CANL is near 0V in this recessive state. Under the ISO 11898 standard, the recessive state is interpreted as a logic high (“1”) level and also as the idle state.

In many CAN system applications, network nodes 102 can be idle much of the time. Particularly in battery-powered systems such as in the automotive context, power consumption is a significant concern. To control its power consumption, transceiver 110 in this example can be placed into standby and sleep modes, in either of which certain circuit functions are powered down to reduce the quiescent power consumed during periods of inactivity. In the standby mode, CAN transceiver 110 neither transmits nor receives data signals at bus CANBus, and certain circuit functions may be powered down. Additional transceiver functions may further be disabled in a sleep mode, if available in the particular transceiver implementation. This description will refer to the standby mode as referring to either of the standby and sleep modes.

Wake-up receiver 210 is provided in CAN transceiver 110 to detect differential signaling on bus CANBus while in the standby mode and to issue a wake-up signal WUP in response to the differential signaling corresponding to a specified wake-up pattern. The wake-up signal may be forwarded to mode and control logic 108 of transceiver 110 itself, and additionally to other circuitry (e.g., MCU 104) in its network node 102.

FIG. 3B is a timing diagram illustrating a wake-up pattern at bus CANBus according to the ISO 11898-2:2024 Annex A standard. As shown in the example of FIG. 3B, this wake-up pattern of states at bus lines CANH, CANL consists of (1) a dominant state for at least a time t_{FILTER}, followed by (2) a recessive state for at least a time t_{FILTER}, followed by (3) another dominant state for at least a time t_{FILTER}, followed by (4) another recessive state for at least a time t_{FILTER}. To enable wake-up, the entire pattern must be completed within a time t_{TM_OUT} (e.g., ranging from 0.5 to 2.0 msec).

The wake-up receiver determines the particular value of time parameter t_{FILTER} used to determine whether a bus state is a valid instance within the wake-up pattern. Two sets of specifications for the time parameter t_{FILTER} are provided by the ISO 11898-2:2024 Annex A standard. According to one specification set, faster bus arbitration is enabled by the time parameter t_{FILTER} in a range from 0.1 usec to 0.95 μsec. The other specification set, which allows for higher noise immunity, is enabled by the time parameter t_{FILTER} in a range from 0.5 μsec to 1.45 μsec.

Wake-up receiver 210 in transceiver 110 according to this example enables detection of a bus wake-up pattern using a time parameter t_{FILTER} within the overlapping range of the two ISO 11898 specification sets, namely from 0.5 μsec to 0.95 μsec. Wake-up detection within this narrow range enables a single implementation to attain fast arbitration without compromising on noise immunity.

However, significant pulse width distortion has been observed in prior art wake-up receivers. This pulse width distortion distorts the pulse widths of wake-up pulses resulting from state transitions at bus lines CANH, CANL. In some cases, pulse width distortion has been observed from common mode voltage variations at bus lines CANH, CANL. In automotive applications in which the common mode voltage can become quite high (e.g., 10 or more volts), the resulting pulse width distortion can be severe, rendering it difficult to reliably detect the wake-up pattern using a narrow range of time parameter t_{FILTER} (e.g., from 0.5 to 0.95 μsec).

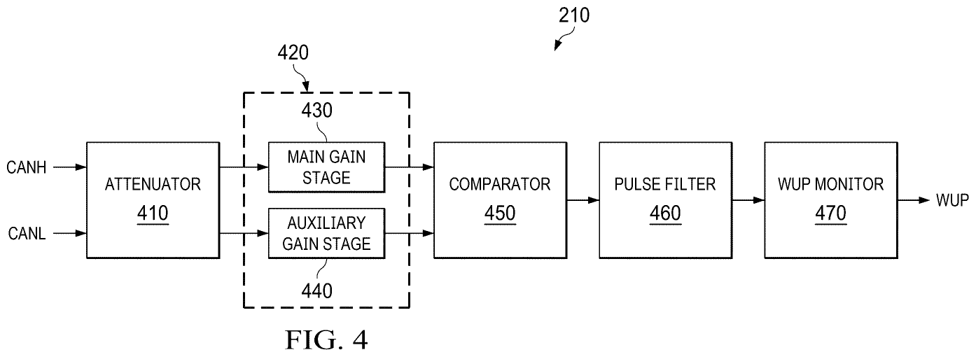

FIG. 4 is a block diagram of wake-up receiver 210 according to an example. Wake-up receiver 210 includes attenuator 410, gain stage 420, comparator 450, pulse filter 460, and wake-up (WUP) monitor logic circuitry 470. Gain stage includes main gain stage 430 and auxiliary gain stage 440.

Attenuator 410 has a pair of inputs coupled to bus lines CANH and CANL, respectively, of bus CANBus. Attenuator 410 may be constructed of resistor dividers or the like, arranged to reduce the voltages at bus lines CANH, CANL to levels suitable for gain stage 420. Gain stage 420 has inputs receiving the attenuated bus signals, and outputs a differential signal to inputs of comparator 450. Comparator 450 converts the differential signal at the outputs of gain stage 420 to a digital signal, and applies that digital signal to an input of pulse filter 460. Pulse filter 460 detects whether the digital signal at its input indicates a valid wake-up pulse, for example by rejecting digital pulses that are shorter in duration than a time parameter t_{FILTER}. Pulse filter 460 forwards a signal indicating receipt of a valid wake-up pulse to an input of WUP monitor 470, which in turn issues a wake-up signal WUP in response to the sequence of valid pulses meeting the specified wake-up pattern (e.g., dominant-recessive-dominant-recessive within a specified time out interval t_{TM_OUT})

The wake-up signal WUP may be forwarded by WUP monitor 370 to mode and control logic 206, which in turn issues one or more signals internally to or externally from transceiver 110. In one example in which transceiver 110 is in sleep mode, mode and control logic 206 may place transceiver into the standby mode, and issue a node interrupt signal at terminal nINT. MCU 104 or other processing circuitry in transceiver 110 may then process the node interrupt to wake-up other circuitry in transceiver 110. In another example in which transceiver 110 is in standby mode, mode and control logic 206 may cause receiver 208 to output signals at data terminal RXD for receipt by MCU 104 or other controller circuitry in transceiver 110, following which transceiver 110 and other circuitry may be placed into a normal operating mode.

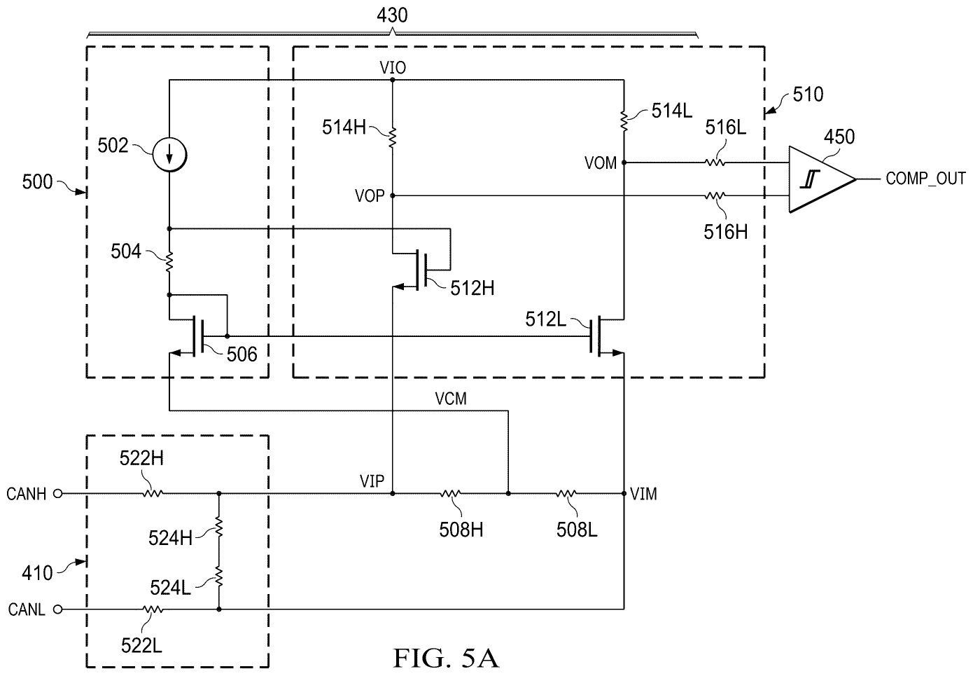

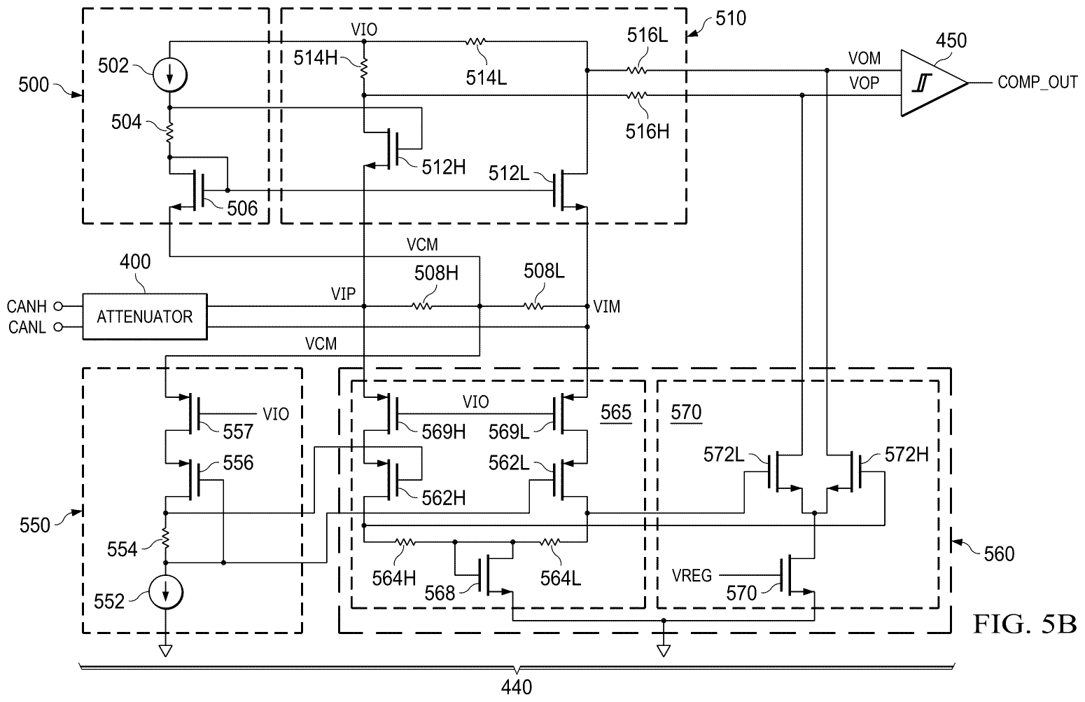

FIG. 5A illustrates an example of main gain stage 430 as incorporated into wake-up receiver 210 along with attenuator 410 and comparator 450. Main gain stage 430 includes offset generation circuit 500, common-gate amplifier 510, and resistors 508H, 508L. Offset generation circuit 500 includes current source 502, resistor 504, and n-channel metal-oxide-semiconductor (NMOS) transistor 506. Common-gate amplifier 510 includes NMOS transistors 512H, 514L, and resistors 514H, 514L, 516H, and 516L. Attenuator 410 includes resistors 522H, 522J, 524H, 524L.

Attenuator 410 in this example is constructed of voltage dividers. A first voltage divider includes resistors 522H and 524H. Resistor 522H has one terminal coupled to bus line CANH and another terminal coupled to one terminal of resistor 524H. A second voltage divider includes resistors 522L and 524L. Resistor 522L has one terminal coupled to bus line CANL and another terminal coupled to one terminal of resistor 524L. Second terminals of resistors 524H and 524L are coupled together. In this example, resistors 522H and 522L have the same resistance as one another, and resistors 524J and 524L have the same resistance as one another. A voltage VIP is established at the node between resistors 522H and 524H, and a voltage VIM is established at the node between resistors 522L and 524L. Voltages VIP and VIM are attenuated versions of the voltages at bus lines CANH, CANL, with the attenuation defined by the voltage divider ratios.

Current source 502 of offset generation circuit 500 has a terminal receiving digital I/O voltage VIO as a power supply voltage (e.g., from voltage regulator 106). Resistor 504 has a first terminal coupled to a second terminal of current source 502 and a second terminal coupled to gate and drain terminals of NMOS transistor 506.

In common-gate amplifier 510, resistor 514H has one terminal receiving the VIO power supply voltage and a second terminal coupled to the drain terminal of NMOS transistor 512H. Resistor 514L similarly has one terminal receiving the VIO power supply voltage and a second terminal coupled to the drain terminal of NMOS transistor 512L. The gate terminal of NMOS transistor 512H is coupled to the first terminal of resistor 504 at current source 502, and the gate terminal of NMOS transistor 512L is coupled to the second terminal of resistor 504 at the drain terminal of NMOS transistor 506. The drain terminal of NMOS transistor 512H is coupled to one terminal of resistor 516H, which has another terminal coupled to an input of comparator 450. Similarly, the drain terminal of NMOS transistor 512l is coupled to one terminal of resistor 516L, which has another terminal coupled to a second input of comparator 450.

Comparator 450 in this example may be constructed as an edge-triggered comparator. Comparator 450 generates signal COMP_OUT at its output in response to the comparison of output voltages VOP, VOM from common-gate amplifier 510 as received at its inputs via resistors 516H, 516L, respectively.

In this example, resistor 508H has a first terminal coupled to attenuator 410, specifically at the node between resistors 522H and 524H, and to the source terminal of NMOS transistor 512H in common-gate amplifier 510. As such, the voltage VIP at one output of attenuator 410 appears at one input of common-gate amplifier 510, specifically at the source of NMOS transistor 512H. Similarly, resistor 508L has a first terminal coupled to attenuator 410, at a node between resistors 524H and 524L, and to the source terminal of NMOS transistor 512L in common-gate amplifier 510. As such, the voltage VIM at the other output of attenuator 410 appears at a second input of common-gate amplifier 510, specifically at the source of NMOS transistor 512L.

Resistors 508H and 508L have terminals coupled together, and to the source terminal of NMOS transistor 506 in offset generation circuit 500. Resistors 508H and 508L have the same resistance as one another in this example. Accordingly, a voltage VCM is established at the node between resistors 508H and 508L, and corresponds to the common mode voltage of the levels at bus lines CANH, CANL.

Resistor 504 in offset generation circuit 500 establishes a differential voltage across the gates of NMOS transistors 512H and 512L based on the resistance of resistor 504 and the current conducted by current source 502 and diode-connected NMOS transistor 506. As such, the gate voltages of NMOS transistors 512H, 512L are relatively stable over dominant and recessive state signals received at bus lines CANH, CANL. Common-gate amplifier 510 generates output voltages VOP, VOM at the drain terminals of NMOS transistors 512H, 512L, respectively, in response to the differential of voltages VIP, VIM at the source terminals of NMOS transistors 512H, 512L in response to differential signaling at bus lines CANH, CANL. Comparator 450 generates an output signal COMP_OUT in response to the polarity of the differential between voltages VOP, VOM at its inputs. In this example, comparator 450 may compare the differential current conducted from voltages VOP, VOM through resistors 516H, 516L, respectively.

In this example, as noted above, offset generation circuit 500 is referenced to the common mode voltage VCM at the node between resistors 508H, 508L, which reflects the common mode voltage at bus lines CANH, CANL. Variations in the bus common mode voltage can be substantial in some CAN network applications, particularly in the automotive context. By referencing offset generation circuit 500 to this common mode voltage VCM, pulse width distortion at the output of main gain stage 430 as a result of common mode voltage variations can be greatly reduced. In addition, the relatively simple arrangement of common-gate amplifier 510 in this example of FIG. 5A enables a high bandwidth for wake-up receiver 210.

In the automotive context in particular, stringent electromagnetic compatibility (EMC) requirements have been applied to electronic components such as CAN transceivers. These EMC requirements refer to emissions of radio frequency (RF) energy from electronic components, and the immunity of the components to RF energy emitted by other devices. Certain types of EMC tests have been devised in order to measure or characterize the RF immunity of components such as CAN transceivers. One such test that has proven useful to detect EMC weakness in CAN transceivers is Direct Power Injection (DPI). In a DPI test, certain nodes in the transceiver are stressed with injected high frequency power, for example stepwise increasing power of up to 30 dBm at frequencies ranging from 1 MHz to 1 GHz. The response of the device to this stress is observed by monitoring analog and digital outputs, and detecting the power levels and frequencies at which functional failures occur.

During EMC tests such as DPI applied to CAN transceivers, the electrical parameters at various nodes in the circuit and network can reach abnormal levels. For example, the common mode voltage VCM at bus lines CANH, CANL has been observed to increase well beyond the VCC or VIO power supply voltage. In the example of wake-up receiver 210 shown in FIG. 5A, the high bandwidth construction of common-gate amplifier 510 is unable to filter out DPI, particularly at frequencies of 10 MHz and below. If the common mode voltage VCM substantially exceeds the power supply voltage, such as during a DPI test, transistors 512H, 512L in common-gate amplifier 510 turn off, effectively disabling wake-up receiver 210 from responding to wake-up pulses.

To address this issue, FIG. 5B illustrates main gain stage 430 in combination with auxiliary gain stage 440 according to an example. In this example, attenuator 400, offset generation 500, common-gate amplifier 510, resistors 508H, 508L, and comparator 450 are provided as described above relative to FIG. 5A. Auxiliary gain stage 440 includes offset generation circuit 550 and auxiliary stage amplifier 560. Offset generation circuit 550 includes current source 552, resistor 554, and p-channel MOS (PMOS) transistors 556 and 557. Auxiliary stage amplifier 560 includes common-gate amplifier 565 and differential amplifier 570. Common-gate amplifier 565 includes PMOS transistors 562H, 562L, 569H, and 569L, and NMOS transistor 568. Differential amplifier 570 includes NMOS transistors 570, 572H, and 572L.

In offset generation circuit 550, current source 552 has a terminal coupled to a common potential (e.g., circuit ground) and another terminal coupled to a terminal of resistor 554 and to a gate terminal of PMOS transistor 556. The drain terminal of PMOS transistor 556 is coupled to another terminal of resistor 554. PMOS transistor 557 has its drain terminal coupled to the source terminal of PMOS transistor 556, and its source terminal coupled to the common terminals of resistors 508H and 508L to receive common mode voltage VCM. The gate terminal of PMOS transistor 557 receives a bias voltage, for example digital I/O voltage VIO generated by a voltage regulator 106 in network node 102. Alternatively, if power supply voltage VCC biases offset generation circuit 500 and common-gate amplifier 510 (instead of voltage VIO as shown), the voltage at the gate terminal of PMOS transistor 557 would also be at power supply voltage VCC.

PMOS transistor 569H in common-gate amplifier 565 has a source terminal coupled to the output of attenuator 400 generating voltage VIP. Similarly, PMOS transistor 569L has a source terminal coupled to the output of attenuator 400 generating voltage VIM. The gate terminals of PMOS transistors 569H and 569L both receive a bias voltage, for example a voltage VIO similarly as PMOS transistor 557 in this example. Alternatively, if power supply voltage VCC biases offset generation circuit 500 and common-gate amplifier 510, the voltage at the gate terminal of PMOS transistor 557 would also be at power supply voltage VCC. PMOS transistor 562H has a source terminal coupled to the drain terminal of PMOS transistor 569H, and a gate terminal coupled to the same terminal of resistor 554 as is coupled to the drain terminal of PMOS transistor 556. One terminal of resistor 564H is coupled to the drain terminal of PMOS transistor 562H, and another terminal of resistor 564H is coupled to the gate and drain terminals of NMOS transistor 568. NMOS transistor 568 is thus diode-connected due to its gate and drain terminals at the same potential, and has a source terminal coupled to circuit ground. In a second leg of common-gate amplifier 565, PMOS transistor 562L has a source terminal coupled to the drain terminal of PMOS transistor 569L, and a gate terminal coupled to the terminal of resistor 554 that is coupled to current source 552. One terminal of resistor 564L is coupled to the drain terminal of PMOS transistor 562L, and another terminal of resistor 564L is coupled to the gate and drain terminals of NMOS transistor 568.

In differential amplifier 570, NMOS transistor 572H has a gate terminal coupled to the drain terminal of PMOS transistor 562H. Similarly, NMOS transistor 572L has a gate terminal coupled to the drain terminal of PMOS transistor 562L. The drain terminal of NMOS transistor 572H is coupled to the same input of comparator 450 as receives signal VOM from common-gate amplifier 510, and the drain terminal of NMOS transistor 572L is coupled to the same input of comparator 450 as receives signal VOP from common-gate amplifier 510. The source terminals of NMOS transistors 572H, 572L are coupled together to the drain terminal of NMOS transistor 570. NMOS transistor 570 has a source terminal coupled to circuit ground, and a gate terminal receiving a regulated voltage VREG, for example from voltage regulator 106.

As mentioned above, common mode voltage VCM at bus lines CANH, CANL has been observed to increase to as high as 2.8V during DPI testing and under certain high voltage operation in the automotive context. As common mode voltage VCM rises above the VIO or VCC power supply voltage (e.g., at 1.7V), the NMOS transistors in offset generation circuit 500 and common-gate amplifier 510 will tend to turn off, inhibiting the response of main gate stage 430 to possible wake-up pulses at bus lines CANH, CANL. Auxiliary gain stage 440 in the example of FIG. 5B maintains the ability of wake-up receiver 210 to respond to possible wake-up pulses under such high common mode voltage conditions.

For example, if voltage VIO at the gates of PMOS transistors 557, 569H, and 569L is on the order of 1.7V, those PMOS transistors will turn on as common mode voltage VCM rises at least a threshold voltage above voltage VIO. In that event, offset generation circuit 550 conducts current from common mode voltage VCM to circuit ground through PMOS transistor 556 and resistor 554. A differential voltage based on the resistance of resistor 554 and the current conducted by current source 552 and PMOS transistor 506 then develops across resistor 554, and is applied across the gate terminals of PMOS transistors 562H, 562L in common-gate amplifier 565. With this bias at the gates of PMOS transistors 562H, 562L, common-gate amplifier 565 can respond to differential signaling at bus lines CANH, CANL by producing a differential voltage at the drain terminals of PMOS transistors 562H, 562L.

This differential voltage at the drain terminals of PMOS transistors 562H, 562L in common-gate amplifier 565 is applied to the gate terminals of NMOS transistors 572H, 572L, respectively, of differential amplifier 570. In response to that differential voltage, differential amplifier 570 generates a differential signal at the VOM, VOP inputs of comparator 450. In response, comparator 450 generates a digital output signal COMP_OUT for application to an input of pulse filter 460 (FIG. 4).

As in the example of offset generation circuit 500, offset generation 550 in auxiliary gain stage 440 is referenced to the common mode voltage VCM at the node between resistors 508H, 508L, which reflects the common mode voltage at bus lines CANH, CANL. This referencing of offset generation circuit 550 to common mode voltage VCM can reduce the pulse width distortion caused by variations in common mode voltage at bus CANBus, which can be substantial especially in the automotive context.

Gain stage 420 in this example is thus able to detect wake-up pulses at bus lines CANH, CANL under direct power injection (DPI) stresses, even if the common mode voltage of bus lines CANH, CANL exceeds the local power supply voltage VCC. For nominal common mode voltage VCM levels at or below the power supply voltage VCC, common-gate amplifier 510 constructed of NMOS transistors in this example can respond to wake-up pulses. If the level of common mode voltage VCM significantly exceeds the power supply voltage VIO or VCC, as the case may be, for example by more than a transistor threshold voltage, auxiliary gain stage 440 can respond to wake-up pulses. This ability is provided in this example without requiring the common-gate amplifier stages to include filtering of DPI conditions. As such, common-gate amplifiers 510 and 565 can each be constructed to have high bandwidth performance, while still attaining low pulse width distortion.

Pulse filter 460 may be constructed as a Schmitt trigger in some implementations of wake-up receiver 210. However, especially for those applications in which wake-up patterns at bus CANBus are to be detected within the tightened limits on time parameter t_{FILTER} specified by the ISO 11898-2:2024 Annex A standard (e.g., 0.5 to 0.95 μsec), only a minimal amount of pulse width distortion due to pulse filter 460 is tolerable. The use of a Schmitt trigger in the pulse filter has been observed to involve significant pulse width distortion to such an extent that, combined with the pulse width distortion from other circuits in the wake-up receiver, may require trimming during manufacture in order to attain the tighter t_{FILTER} specification. In addition, minimal quiescent current by the pulse filter is desirable, especially for battery-powered applications such as in the automotive context.

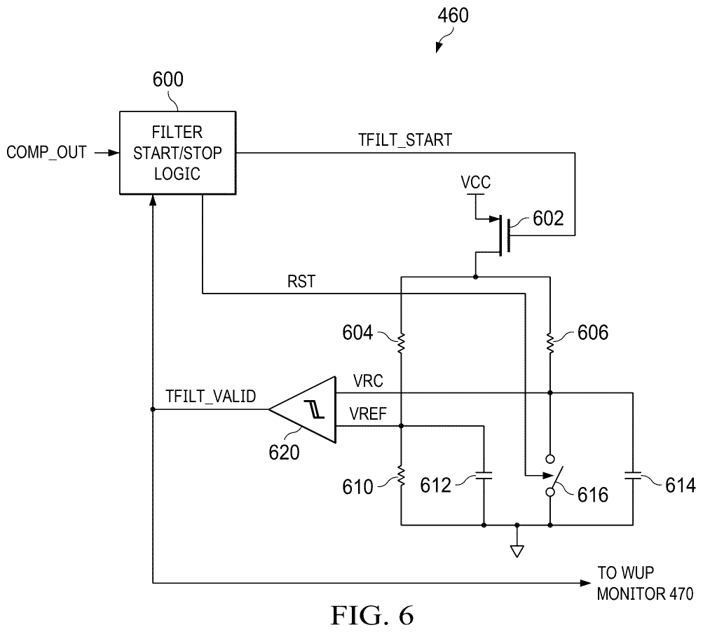

FIG. 6 illustrates an example pulse filter 460 constructed to minimize pulse width distortion and quiescent current conduction. Pulse filter 460 in this example includes filter start/stop logic 600, PMOS transistor 602, resistors 604, 606, and 610, capacitors 612 and 614, switch 616, and comparator 620.

Start/stop logic 600 of pulse filter 460 has one input coupled to the output of comparator 450 (FIGS. 5A and 5B) to receive the signal COMP_OUT, and another input coupled to an output of comparator 620 to receive a signal TFILT_VALID. In this example, start/stop logic 600 may be constructed as sequential logic (e.g., a state machine), and has one output presenting a signal TFILT_START and another output presenting a reset signal RST.

PMOS transistor 602 has a source terminal coupled to a power supply terminal, for example to receive power supply voltage VCC, and a gate terminal coupled to the output of start/stop logic 600 to receive signal TFILT_START. In one leg of pulse filter 460, resistor 604 has one terminal coupled to a drain terminal of PMOS transistor 602, and another terminal coupled to one terminal of resistor 610, one terminal of capacitor 612, and one input of comparator 620. Resistor 610 has another terminal coupled to a common potential (e.g., circuit ground), and capacitor 612 similarly has another terminal coupled to the common potential.

In another leg of pulse filter 460, resistor 606 has one terminal coupled to a drain terminal of PMOS transistor 602, and another terminal coupled to one terminal of capacitor 614, one terminal of switch 616, and another input of comparator 620. Capacitor 614 has another terminal coupled to the common potential (e.g., circuit ground), and switch 616 similarly has another terminal coupled to the common potential. Switch 616 has a control terminal coupled to the output of start/stop logic presenting the reset signal RST. Switch 616 may be constructed as a MOS transistor or MOS pass gate, for example.

In operation, the resistance values of resistors 604 and 610, and the capacitance of capacitor 612, are selected to establish a first time constant for a voltage VREF that develops at the node between resistor 604, on one hand, and resistor 610 and capacitor 612 on the other hand, in response to PMOS transistor 602 turning on. The voltage divider established by resistors 604 and 610 determines the asymptotic voltage to which this voltage VREF is charged. Voltage VREF at this node is applied to one input of comparator 620.

Similarly, the resistance value of resistor 606 and the capacitance of capacitor 614 are selected to establish a second time constant for a voltage VRC that develops at the node between resistor 606 and capacitor 614 in response to PMOS transistor 602 turning on. This voltage VRC is applied to the other input of comparator 620. In this example, the first time constant established by the resistances of resistors 604, 610 and the capacitance of capacitor 612, is shorter than the second time constant established by the resistance of resistor 606 and the capacitance of capacitor 614. In this example, the relationship between the second time constant and the asymptotic voltage to which voltage VREF is charged is selected to correspond to the time parameter t_{FILTER}. Switch 616, when turned on by reset signal RST from start/stop logic 600, grounds the voltage VRC.

The output of comparator 620 presents the signal TFILT_VALID, and is coupled to an input of start/stop logic 600. The output of comparator 620 is also coupled to an input of WUP monitor 470. In this example, the signal TFILT_VALID indicates the receipt of a valid pulse (e.g., of a duration exceeding the time t_{FILTER}) at bus lines CANH, CANL, corresponding to a wake-up pulse. WUP monitor 470 can process this indication in its determination of whether a wake-up pattern is being or has been received by wake-up receiver 210, and its issuing of wake-up signal WUP when appropriate.

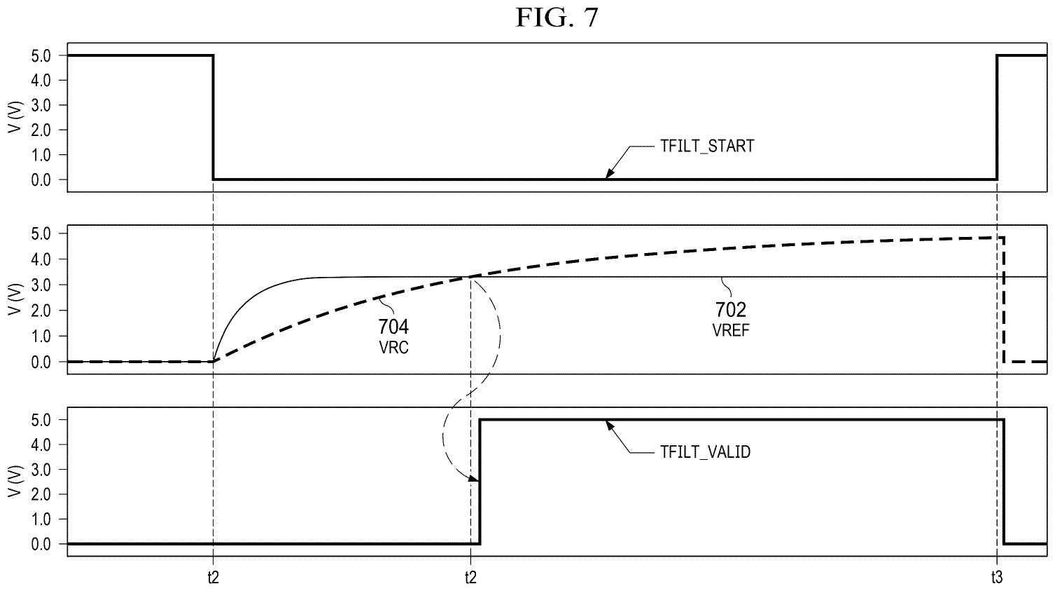

FIG. 7 is a timing diagram illustrating the operation of pulse filter 460 according to an example. In operation, a transition of signal COMP_OUT from edge-triggered comparator 450 in this example occurs in response to the beginning of either a dominant or recessive state at bus lines CANH, CANL, as presented at the outputs VOP, VOM of gain stage 420. In response to this transition, start/stop logic 600 issues signal TFILT_START (e.g., at a low logic level) at time t1, which turns on PMOS transistor 602. This turning on of PMOS transistor 602 initiates the charging of capacitors 612 and 614 via their respective resistors 604 and 606.

The time constant for the charging of voltage VREF is shorter than the time constant for the charging of voltage VRC, as described above for this example. FIG. 7 shows plots 702 and 704 corresponding to voltages VREF and VRC, respectively. As shown in the example of FIG. 7, voltage VREF (plot 702) charges more quickly to its asymptotic voltage after time t1 than does voltage VRC (plot 704). Comparator 620 compares voltages VRC and VREF at its inputs. At such time as voltage VRC reaches the level of voltage VREF, which occurs at time t2 in the example of FIG. 7, comparator 620 issues signal TFILT_VALID at its output (e.g., as a low-to-high logic level transition).

At the end of the current dominant or recessive state at bus lines CANH, CANL as presented by gain stage 420 to the inputs of comparator 450, the pulse of signal COMP_OUT ends. FIG. 7 illustrates this event at time t3. In response, start/stop logic 600 issues a transition of the signal TFILT_START (e.g., a low-to-high transition), turning off PMOS transistor 602 in pulse filter 460. In addition, start/stop logic 600 may issue a reset signal RST to close switch 616, grounding voltage VRC as shown in FIG. 7. In response, comparator 620 causes a transition of signal TFILT_VALID (e.g., a high-to-low transition). With PMOS transistor 602 off, voltage VREF eventually discharges to ground through resistor 610.

As noted above, the relationship between the time constant for the charging of voltage VRC and the asymptotic voltage to which voltage VREF is charged is selected to correspond to the time parameter t_{FILTER}. Stated another way, the duration between time t1 and time t2 in FIG. 7 corresponds to time parameter t_{FILTER}. If the dominant state at bus lines CANH, CANL ends prior to elapse of time parameter t_{FILTER} (e.g., prior to time t2), voltage VRC will not have charged to the level of voltage VREF. In this event, start/stop logic 600 will have turned off PMOS transistor 602 and closed switch 616 prior to comparator 620 issuing the signal TFILT_VALID for that instance of the dominant state. As a result, pulse filter 460 detects dominant state pulses at bus lines CANH, CANL of a duration of at least the time parameter t_{FILTER} (e.g., 0.5 μsec), and filters out dominant and recessive state pulses of duration shorter than time parameter t_{FILTER} from application to WUP monitor 470.

Important advantages are enabled according to these examples. A gain stage in a wake-up receiver for CAN transceiver devices can be constructed that is capable of accurate operation over a wide range of common mode and differential voltages at the bus lines, with high bandwidth and while requiring low levels of quiescent current. In addition, such a gain stage can be constructed to operate under high voltages conditions, such as those modeled by Direct Power Injection tests. In addition, an accurate pulse filter can be provided in a wake-up receiver for CAN transceiver devices, with minimum pulse width distortion attainable without requiring trimming during manufacture, while also attaining low quiescent current conduction. These and other advantages may be enabled according to the described examples.

Examples are described in this specification as implemented into CAN transceiver devices as such implementation can be advantageous in that context. However, aspects of these examples may be beneficially applied in alternative applications, for example those having standby modes that can be exited in response to wake-up pulses. Accordingly, the above description is provided by way of example only, and is not intended to limit the true scope as claimed.

As used herein, the terms “terminal”, “node”, “interconnection” and “pin” are used interchangeably. Unless specifically stated to the contrary, these terms are generally used to mean an interconnection between or a terminus of a device element, a circuit element, an integrated circuit, a device, or other electronics or semiconductor component.

Unless otherwise stated, “about,” “approximately,” or “substantially” preceding a value means+/−10 percent of the stated value. Modifications are possible in the described examples, and other examples are possible within the scope of the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party. While, in some example embodiments, certain elements are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

Modifications to the described examples, and other examples, are possible within the scope of the claims.

What is claimed is:

1. Receiver circuitry, comprising:
a first circuit comprising:
a first transistor, having first and second terminals and a control terminal, the second terminal coupled to the control terminal;
a first resistor, having a first terminal coupled to the second terminal of the first transistor, and having a second terminal;
a first current source, coupled to the second terminal of the first resistor;
a second circuit comprising:
a second transistor having first and second terminals, and having a control terminal coupled to the second terminal of the first resistor;
a third transistor having first and second terminals, and having a control terminal coupled to the first terminal of the first resistor;
a second resistor having a first terminal coupled to a first input and to the first terminal of the second transistor, and having a second terminal coupled to the first terminal of the first transistor;
a third resistor having a first terminal coupled to a second input and to the first terminal of the third transistor, and having a second terminal coupled to the first terminal of the first transistor and to the second terminal of the second resistor; and
a first comparator, having a first input coupled to the second terminal of the second transistor, and having a second input coupled to the second terminal of the third transistor.

2. The circuitry of claim 1, further comprising:
an attenuator coupled to the first and second inputs, and having outputs coupled to the first terminals of the second and third resistors.

3. The circuitry of claim 2, wherein the attenuator comprises:
a fourth resistor having a first terminal coupled to the first input, and having a second terminal coupled to the first terminal of the second resistor;
a fifth resistor having a first terminal coupled to the second input, and having a second terminal coupled to the first terminal of the third resistor; and
a sixth resistor having a first terminal coupled to the second terminal of the fourth resistor, and having a second terminal coupled to the second terminal of the fifth resistor.

4. The circuitry of claim 1, wherein the second circuit further comprises:
a first load device having a first terminal coupled to the second terminal of the second transistor, and having a second terminal; and
a second load device having a first terminal coupled to the second terminal of the third transistor, and having a second terminal coupled to the second terminal of the first load device.

5. The circuitry of claim 1, further comprising a third circuit, the third circuit comprising:
a fourth circuit, comprising:
a fourth transistor, having a first terminal coupled to the second terminals of the second and third resistors, and having a second terminal and a control terminal;
a fifth transistor, having a first terminal coupled to the second terminal of the fourth transistor, and having a second terminal and a control terminal;
a seventh resistor, having a first terminal coupled to the second terminal of the fifth transistor, and having a second terminal;
a second current source, having a first terminal coupled to the second terminal of the seventh resistor and to the control terminal of the fifth resistor;
a fifth circuit, comprising:
a sixth transistor, having a first terminal coupled to the first input and to the first terminal of the second resistor, and having a second terminal and a control terminal;
a seventh transistor, having a first terminal coupled to the second input and to the first terminal of the third resistor, having a second terminal, and having a control terminal coupled to the control terminal of the sixth transistor;
an eighth transistor, having a first terminal, having a second terminal, and having a control terminal coupled to its second terminal;
a ninth transistor having a first terminal coupled to the second terminal of the sixth transistor, having a second terminal coupled to the second terminal of the eighth transistor, and having a control terminal coupled to the first terminal of the seventh resistor; and
a tenth transistor having a first terminal coupled to the second terminal of the seventh transistor, having a second terminal coupled to the second terminal of the eighth transistor, and having a control terminal coupled to the second terminal of the seventh resistor; and
a differential amplifier, having first and second inputs coupled to the second terminals of the ninth and tenth transistors, respectively, and having first and second outputs coupled to the first and second inputs of the first comparator.

6. The circuitry of claim 5, wherein the differential amplifier comprises:
a third current source;
an eleventh transistor having a first terminal coupled to the third current source, having a second terminal coupled to the second input of the first comparator, and having a control terminal coupled to the second terminal of the ninth transistor;
a twelfth transistor having a first terminal coupled to the third current source, having a second terminal coupled to the first input of the first comparator, and having a control terminal coupled to the second terminal of the tenth transistor.

7. The circuitry of claim 5, wherein the first, second, and third transistors are metal-oxide-semiconductor (MOS) transistors of a first channel conductivity type;
and wherein the fourth, fifth, sixth, seventh, ninth, and tenth transistors are MOS transistors of a second channel conductivity type.

8. The circuitry of claim 1, further comprising:
a pulse filter having an input coupled to an output of the comparator, and having an output; and
wake-up monitor logic, having an input coupled to the output of the pulse filter.

9. The circuitry of claim 5, wherein the pulse filter comprises:
logic circuitry having a first input coupled to the output of the first comparator;
a thirteenth transistor, having a first terminal, having a second terminal, and having a control terminal coupled to an output of the logic circuitry;
a second comparator, having an output coupled to a second input of the logic circuitry and to an input of the wake-up monitor logic;
an eighth resistor, having a first terminal coupled to the second terminal of the thirteenth transistor, and having a second terminal;
a first capacitor, having a first terminal coupled to the second terminal of the eighth resistor and to a first input of the second comparator, and having a second terminal;
a ninth resistor, having a first terminal coupled to the second terminal of the thirteenth transistor, and having a second terminal; and
a second capacitor, having a first terminal coupled to the second terminal of the ninth resistor and to a second input of the second comparator, and having a second terminal.

10. The circuitry of claim 9, wherein the pulse filter further comprises:
a tenth resistor having a first terminal coupled to the first terminal of the first capacitor.

11. The circuitry of claim 10, wherein the eighth and tenth resistors and first capacitor establish a first time constant;
and wherein the ninth resistor and second capacitor establish a second time constant longer than the first time constant.

12. Receiver circuitry, comprising:
an attenuator, having first and second bus inputs and first and second outputs;
a gain stage, having first and second inputs coupled to the first and second outputs of the attenuator, respectively, and having first and second outputs;
a first comparator, having a first and second inputs coupled to the first and second outputs of the gain stage, respectively, and having an output;
a pulse filter, comprising:
logic circuitry having a first input coupled to the output of the first comparator;
a first transistor, having a first terminal, having a second terminal, and having a control terminal coupled to an output of the logic circuitry;
a second comparator, having first and second inputs, and having an output coupled to a second input of the logic circuitry;
a first resistor, having a first terminal coupled to the second terminal of the first transistor, and having a second terminal;
a first capacitor, having a first terminal coupled to the second terminal of the first resistor and to a first input of the second comparator, and having a second terminal;
a second resistor, having a first terminal coupled to the second terminal of the first transistor, and having a second terminal; and
a second capacitor, having a first terminal coupled to the second terminal of the second resistor and to the second input of the comparator, and a second terminal; and
wake-up monitor logic, having an input coupled to the output of the second comparator.

13. The circuitry of claim 12, wherein the pulse filter further comprises:
a third resistor coupled to the first terminal of the first capacitor.

14. The circuitry of claim 13, wherein the first and third resistors and first capacitor establish a first time constant;
and wherein the second resistor and second capacitor establish a second time constant longer than the first time constant.

15. The circuitry of claim 12, wherein the gain stage comprises:
a second transistor, having first and second terminals, and having a control terminal coupled to its second terminal;
a fourth resistor, having a first terminal coupled to the second terminal of the second transistor, and having a second terminal;
a first current source, coupled to the second terminal of the fourth resistor;
a third transistor having first and second terminals, and having a control terminal coupled to the second terminal of the fourth resistor;
a fourth transistor having first and second terminals, and having a control terminal coupled to the first terminal of the fourth resistor;
a fifth resistor having a first terminal coupled to the first output of the attenuator and to the first terminal of the third transistor, and having a second terminal coupled to the first terminal of the second transistor; and
a sixth resistor having a first terminal coupled to the second output of the attenuator and to the first terminal of the fourth transistor, and having a second terminal coupled to the first terminal of the second transistor and to the second terminal of the seventh resistor.

16. The circuitry of claim 15, wherein the gain stage further comprises:
a seventh transistor, having a first terminal coupled to the second terminals of the fifth and sixth resistors, and having a second terminal and a control terminal;
an eighth transistor, having a first terminal coupled to the second terminal of the seventh transistor, and having a second terminal and a control terminal;
a seventh resistor, having a first terminal coupled to the second terminal of the eighth transistor, and having a second terminal;
a second current source, having a first terminal coupled to the second terminal of the seventh resistor;
a ninth transistor, having a first terminal coupled to the first output of the attenuator and to the first terminal of the fifth resistor, and having a second terminal and a control terminal;
a tenth transistor, having a first terminal coupled to the second output of the attenuator and to the first terminal of the sixth resistor, having a second terminal, and having a control terminal coupled to the control terminal of the ninth transistor;
an eleventh transistor having a first terminal coupled to the second terminal of the ninth transistor, having a second terminal, and having a control terminal coupled to the first terminal of the seventh resistor;
a twelfth transistor having a first terminal coupled to the second terminal of the tenth transistor, having a second terminal, and having a control terminal coupled to the second terminal of the seventh resistor;
a thirteenth transistor, having a first terminal, having a second terminal coupled to the second terminals of the eleventh and twelfth transistors, and having a control terminal coupled to its second terminal; and
a differential amplifier, having first and second inputs coupled to the second terminals of the eleventh and twelfth transistors, respectively, and having first and second outputs coupled to the first and second inputs of the first comparator.

17. A controller area network (CAN) transceiver, comprising:
a transmitter, having first and second outputs coupled to first and second bus terminals, respectively;
a receiver, having first and second inputs coupled to the first and second bus terminals, respectively; and
a wake-up receiver comprising:
an attenuator, having first and second inputs coupled to the first and second bus terminals, respectively, and first and second outputs;
a gain stage, comprising:
a first transistor, having first and second terminals and a control terminal, the second terminal coupled to the control terminal;
a first resistor, having a first terminal coupled to the second terminal of the first transistor, and having a second terminal;
a first current source, coupled to the second terminal of the first resistor;
a second transistor having first and second terminals, and having a control terminal coupled to the second terminal of the first resistor;
a second resistor having a first terminal coupled to the second terminal of the second transistor, and having a second terminal coupled to a power supply terminal;
a third transistor having first and second terminals, and having a control terminal coupled to the first terminal of the first resistor;
a third resistor having a first terminal coupled to the second terminal of the third transistor, and having a second terminal;
a fourth resistor having a first terminal coupled to the first output of the attenuator and to the first terminal of the second transistor, and having a second terminal; and
a fifth resistor having a first terminal coupled to the second output of the attenuator and to the first terminal of the third transistor, and having a second terminal coupled to the first terminal of the first transistor and to the second terminal of the fourth resistor;
a first comparator, having a first and second inputs coupled to the second terminals of the second and third transistors, respectively, and having an output;
a pulse filter; and
wake-up monitor logic, having an input coupled to the output of the second comparator.

18. The transceiver of claim 17, wherein the pulse filter comprises:
logic circuitry having a first input coupled to the output of the first comparator;
a fourth transistor, having a first terminal, a second terminal, and a control terminal coupled to an output of the logic circuitry;
a second comparator, having first and second inputs, and an output coupled to a second input of the logic circuitry;
a sixth resistor, having a first terminal coupled to the second terminal of the fourth transistor, and a second terminal;
a first capacitor, having a first terminal coupled to the second terminal of the sixth resistor and to the first input of the second comparator, and a second terminal;
a seventh resistor, having a first terminal coupled to the second terminal of the fourth transistor, and a second terminal; and
a second capacitor, having a first terminal coupled to the second terminal of the seventh resistor and to the second input of the second comparator, and a second terminal.

19. The transceiver of claim 17, wherein the gain stage further comprises:
a fifth transistor, having a first terminal coupled to the second terminals of the fourth and fifth resistors, and having a second terminal and a control terminal;
a sixth transistor, having a first terminal coupled to the second terminal of the fifth transistor, and having a second terminal and a control terminal;
an eighth resistor, having a first terminal coupled to the second terminal of the sixth transistor, and having a second terminal;
a second current source, having a first terminal coupled to the second terminal of the eighth resistor;
a seventh transistor, having a first terminal coupled to the first output of the attenuator and to the first terminal of the fourth resistor, and having a second terminal and a control terminal;
an eighth transistor, having a first terminal coupled to the second output of the attenuator and to the first terminal of the fifth resistor, having a second terminal, and having a control terminal coupled to the control terminal of the seventh transistor;
a ninth transistor, having a first terminal coupled to the second terminal of the seventh transistor, having a second terminal, and having a control terminal coupled to the first terminal of the eighth resistor;
a tenth transistor, having a first terminal coupled to the second terminal of the eighth transistor, having a second terminal, and having a control terminal coupled to the second terminal of the eighth resistor;
an eleventh transistor, having a first terminal, having a second terminal coupled to the second terminals of the ninth and tenth transistors, and having a control terminal coupled to its second terminal; and
a differential amplifier, having first and second inputs coupled to the second terminals of the tenth and eleventh transistors, respectively, and having first and second outputs coupled to the first and second inputs of the first comparator.

20. The transceiver of claim 17, wherein the attenuator comprises:
a ninth resistor having a first terminal coupled to the first input, and a second terminal coupled to the first terminal of the fourth resistor;
a tenth resistor having a first terminal coupled to the second input, and a second terminal coupled to the first terminal of the fifth resistor; and
an eleventh resistor having a first terminal coupled to the second terminal of the ninth resistor, and having a second terminal coupled to the second terminal of the tenth resistor.

21. The transceiver of claim 18, wherein the pulse filter further comprises:
a twelfth resistor coupled to the first terminal of the first capacitor;
wherein the sixth and twelfth resistors and first capacitor establish a first time constant;
and wherein the seventh resistor and second capacitor establish a second time constant longer than the first time constant.
